(19) United States
(12) Patent Application Publication
(10) Pub. No.: US 2007/0205410 A1
(43) Pub. Date: Sep. 6, 2007

(54) LIGHT-EMITTING ELEMENT, LIGHT-EMITTING DEVICE, AND ELECTRONIC DEVICE

(75) Inventors: Hisao Ikeda, Atsugi (JP); Yasuo Nakamura, Tokyo (JP); Tomoya Aoyama, Atsugi (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/677,910

(22) Filed: Feb. 22, 2007

(30) Foreign Application Priority Data
Mar. 3, 2006 (JP) 2006-058744

(51) Int. Cl. H01L 29/08

(52) U.S. Cl. 257/40

(57) ABSTRACT

It is an object to provide a light-emitting element having high light-emitting efficiency, which includes a first electrode, a second electrode, and a light-emitting layer between the first electrode and the second electrode, where the light-emitting layer contains a base material, a first impurity element, a second impurity element, and an organic compound; the base material is an inorganic compound containing an element belonging to Group 2 and an element belonging to Group 16 of the periodic table, or an inorganic compound containing an element belonging to Group 12 and an element belonging to Group 16 of the periodic table; the first impurity element is any of copper (Cu), silver (Ag), gold (Au), platinum (Pt), arsenic (As), phosphorus (P), or palladium (Pd); and the second impurity element is any of fluorine (F), chlorine (Cl), bromine (Br), iodine (I), boron (B), aluminum (Al), gallium (Ga), indium (In), or thallium (Tl).

### BACKGROUND OF THE INVENTION

1. Field of the Invention

The present invention relates to a light-emitting element utilizing electroluminescence. In addition, the present invention relates to a light-emitting device and an electronic device including the light-emitting element.

2. Description of the Related Art

In recent years, thin and flat display devices have been required as display devices in a television, a mobile phone, a digital camera, and the like, and as the display devices satisfying this requirement, display devices using self light-emitting elements have attracted attention. One of the self light-emitting elements is a light-emitting element utilizing electroluminescence (EL), and this light-emitting element includes a light-emitting material interposed between a pair of electrodes and can provide light-emission from the light-emitting material by voltage application.

Such a self light-emitting element has advantages over a liquid crystal display, such as high visibility of the pixels and no need of a backlight and is considered to be suitable for a flat panel display element. Another major advantage of such a light-emitting element is that it can be manufactured to be thin and lightweight. In addition, extremely high response speed is also an advantage.

Further, such a self light-emitting element can be formed into a film shape; therefore, plane light-emission can be easily obtained through formation of a large-area element. Since this feature is hard to be obtained in a point light source typified by an incandescent lamp or an LED, or a linear light source typified by a fluorescent lamp, the self light-emitting element has high utility as a plane light source which is applicable to a lighting system or the like.

Light-emitting elements utilizing electroluminescence are classified according to whether a light-emitting material is an organic compound or an inorganic compound. In general, the former is referred to as an organic EL element, and the latter is referred to as an inorganic EL element.

Inorganic EL elements are classified according to their element structures into a dispersed inorganic EL element and a thin-film inorganic EL element. They are different from each other in that the former includes a light-emitting layer in which particles of a light-emitting material are dispersed in a binder and the latter includes a light-emitting layer formed of a thin film of a fluorescent material. However, their mechanisms are common, and light-emission is obtained through collision excitation of a base material or a light-emitting material caused by electrons accelerated by a high electric field. Inorganic light-emitting materials used for the inorganic EL element generally have low quantum efficiency. In recent years, fluorescent materials using an inorganic material have been actively examined. However, among them, even a nanocrystal that is a material having high quantum efficiency has quantum efficiency that is as low as 85% (refer to Non Patent Document 1: H. Bao, and three others, Chemistry of Materials, Vol. 16 (20), 3853-3859 (2004)).

Quantum efficiency of a light-emitting material has a great influence on light-emitting efficiency of the light-emitting element. Through the use of a material with low quantum efficiency as the light-emitting material, light-emitting efficiency of the light-emitting element becomes low.

### SUMMARY OF THE INVENTION

In view of the foregoing problems, it is an object of the present invention to provide a light-emitting element having high light-emitting efficiency. In addition, it is another object to provide a light-emitting device and an electronic device in which power consumption is reduced through the use of the light-emitting element.

The present inventors have found that a light-emitting element has high light-emitting efficiency by using an organic compound with high quantum efficiency for a light-emitting material instead of an inorganic material with low quantum efficiency.

Therefore, one feature of the present invention is a light-emitting element including a light-emitting layer between a pair of electrodes (a first electrode and a second electrode), where the light-emitting layer contains at least a base material, a first impurity element, a second impurity element, and an organic compound.

In addition, another feature of the present invention is a light-emitting element including a first electrode, a second electrode, and a light-emitting layer between the first electrode and the second electrode, where the light-emitting layer contains a base material, a first impurity element, a second impurity element, and an organic compound; the base material is an inorganic compound containing an element belonging to Group 2 of the periodic table and an element belonging to Group 16 of the periodic table, or an inorganic compound containing an element belonging to Group 12 of the periodic table and an element belonging to Group 16 of the periodic table; the first impurity element is any of copper (Cu), silver (Ag), gold (Au), platinum (Pt), arsenic (As), phosphorus (P), or palladium (Pd); and the second impurity element is any of fluorine (F), chlorine (Cl), bromine (Br), iodine (I), boron (B), aluminum (Al), gallium (Ga), indium (In), or thallium (Tl).

In addition, another aspect of the present invention is a light-emitting element including a first electrode, a second electrode, and a light-emitting layer between the first electrode and the second electrode, where the light-emitting layer contains a base material, a first impurity element, a second impurity element, a third impurity element, and an organic compound; the base material is an inorganic compound containing an element belonging to Group 2 of the periodic table and an element belonging to Group 16 of the periodic table, or an inorganic compound containing an element belonging to Group 12 of the periodic table and an element belonging to Group 16 of the periodic table; the first impurity element is any of copper (Cu), silver (Ag), gold (Au), platinum (Pt), arsenic (As), phosphorus (P), or palladium (Pd); the second impurity element is any of fluorine (F), chlorine (Cl), bromine (Br), iodine (I), boron (B), aluminum (Al), gallium (Ga), indium (In), or thallium (Tl); and the third impurity element is any of manganese (Mn) or lanthanoid (Ln).

In addition, another aspect of the present invention is a light-emitting element including a first electrode, a second electrode, and a light-emitting layer and an insulating layer between the first electrode and the second electrode, where the light-emitting layer contains a base material, a first impurity element, a second impurity element, and an organic compound; the base material is an inorganic compound containing an element belonging to Group 2 of the periodic table and an element belonging to Group 16 of the periodic table, or an inorganic compound containing an element belonging to Group 12 of the periodic table and an element belonging to Group 16 of the periodic table; the first impurity element is any of copper (Cu), silver (Ag), gold (Au), platinum (Pt), arsenic (As), phosphorus (P), or palladium (Pd); the second impurity element is any of fluorine (F), chlorine (Cl), bromine (Br), iodine (I), boron (B), aluminum (Al), gallium (Ga), indium (In), or thallium (Tl); and the insulating layer is in contact with the first electrode or the second electrode.

In addition, another aspect of the present invention is a light-emitting element including a first electrode, a second electrode, and a light-emitting layer and an insulating layer between the first electrode and the second electrode, where the light-emitting layer contains a base material, a first impurity element, a second impurity element, a third impurity element, and an organic compound; the base material is an inorganic compound containing an element belonging to Group 2 of the periodic table and an element belonging to Group 16 of the periodic table, or an inorganic compound containing an element belonging to Group 12 of the periodic table and an element belonging to Group 16 of the periodic table; the first impurity element is any of copper (Cu), silver (Ag), gold (Au), platinum (Pt), arsenic (As), phosphorus (P), or palladium (Pd); the second impurity element is any of fluorine (F), chlorine (Cl), bromine (Br), iodine (I), boron (B), aluminum (Al), gallium (Ga), indium (In), or thallium (Tl); the third impurity element is any of manganese (Mn) or lanthanoid (Ln); and the insulating layer is in contact with the first electrode or the second electrode.

In addition, another feature of the present invention is a light-emitting element, where the base material is any of zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), zinc oxide (ZnO), yttrium oxide (Y₂O₃), aluminum nitride (AlN), gallium nitride (GaN), indium nitride (InN), zinc selenide (ZnSe), zinc telluride (ZnTe), zinc-gallium oxide (ZnGa₂O₄), strontium-gallium sulfide (SrGa₂S₄), barium-aluminum sulfide (BaAl₂S₄), barium-zinc sulfide (Ba₂ZnS₃), calcium-gallium sulfide (CaGa₂S₄), barium-silicon sulfide (BaSiS₄), or calcium-aluminum sulfide (CaAl₂S₄).

In addition, another feature of the present invention is a light-emitting element, where the organic compound contained in the light-emitting layer is a fluorescent substance having quantum efficiency of greater than or equal to 50%.

In addition, another feature of the present invention is a light-emitting element, where the organic compound contained in the light-emitting layer is a phosphorescent substance having quantum efficiency of greater than or equal to 50%.

In addition, the present invention includes, in its scope, a light-emitting device including the above-described light-emitting element. The light-emitting device in this specification includes, in its category, an image display device, a light-emitting device, and a light source (including a lighting system). Further, the light-emitting device includes all of the following modules: a module in which a connector such as an FPC (Flexible Printed Circuit), a TAB (Tape Automated Bonding) tape, or a TCP (Tape Carrier Package) is attached to a panel provided with light-emitting elements; a module having a TAB tape or a TCP provided with a printed wiring board at the end thereof; and a module having an IC (Integrated Circuit) directly mounted on a light-emitting element by a COG (Chip On Glass) method.

The present invention also includes, in its scope, an electronic device using the light-emitting element of the present invention in a display portion. Therefore, one feature of the electronic device of the present invention is to include a display portion which includes the above-described light-emitting element and a controller that controls light-emission of the light-emitting element.

Since a light-emitting element of the present invention can convert electric energy to light efficiently, intended luminance can be obtained with much less electric power. In addition, chromaticity can be easily adjusted through selection of a fluorescent organic material or a phosphorescent organic material to be combined. Further, since excited molecules are generated without becoming organic molecules in a radical cation state or a radical anion state, reliability of an element can be enhanced.

In addition, since a light-emitting device of the present invention includes an element which emits light efficiently, power consumption can be reduced. Further, a highly reliable device can be provided, which can emit light of various colors clearly since chromaticity can be easily adjusted.

In addition, since an electronic device of the present invention includes an element which emits light efficiently, power consumption can be reduced. Further, a highly reliable device can be provided, which can display various colors clearly since chromaticity can be easily adjusted.

### BRIEF DESCRIPTION OF THE DRAWINGS

FIG. 1 is a schematic view showing a light-emission mechanism;

FIG. 2 is a schematic view showing a light-emission mechanism;

FIG. 3 is a view showing an example of a light-emitting element of the present invention;

FIGS. 4A to 4C are views each showing an example of a light-emitting element of the present invention;

FIG. 5 is a view explaining a light-emitting device of the present invention;

FIGS. 6A and 6B are views each explaining a light-emitting device of the present invention;

FIGS. 7A to 7D are views each explaining an electronic device of the present invention;

FIG. 8 is a view explaining an electronic device of the present invention;

FIG. 9 is a view explaining an electronic device of the present invention;

FIG. 10 is a view explaining an electronic device of the present invention;

FIG. 11 is a view explaining a lighting system of the present invention;

FIG. 12 is a diagram showing voltage-luminance characteristics of light-emitting elements of Embodiment 1; and

FIG. 13 is a diagram showing electroluminescence (EL) spectra of light-emitting elements of Embodiment 1.

### DESCRIPTION OF THE INVENTION

Hereinafter, Embodiment Modes and Embodiment of the present invention will be explained in detail with reference to the accompanying drawings. It is to be noted that the present invention is not limited to the following description, and it is easily understood by those skilled in the art that modes and details thereof can be modified in various ways without departing from the spirit and the scope of the present invention. Therefore, the present invention should not be interpreted as being limited to the following description of the embodiment modes and the embodiment.

### Embodiment Mode 1

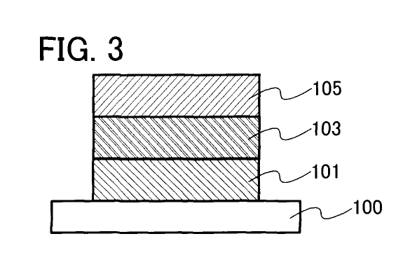

First, a light-emitting element according to the present invention will be explained with reference to FIG. 3.

The light-emitting element shown in this embodiment mode has an element structure including, over a substrate 100, a first electrode 101, a second electrode 105, and a light-emitting layer 103 between the first electrode and the second electrode.

The substrate 100 is used as a supporting body of the light-emitting element. As the substrate 100, for example, glass, quartz, plastics, or the like can be used. Further, other materials can also be used as the substrate 100 as long as they serve as a supporting body of the light-emitting element in the manufacturing process of the light-emitting element.

As the first electrode 101 and the second electrode 105, a metal, an alloy, a conductive compound, a mixture thereof, or the like can be used. Specifically, for example, indium oxide-tin oxide (Indium Tin Oxide: ITO), indium oxide-tin oxide containing silicon or silicon oxide, indium oxide-zinc oxide (Indium Zinc Oxide: IZO), indium oxide containing tungsten oxide and zinc oxide, or the like can be used. These conductive metal oxide films are generally formed by a sputtering method. For example, indium oxide-zinc oxide (IZO) can be formed by a sputtering method using a target in which 1 to 20 wt % zinc oxide is added to indium oxide. In addition, indium oxide containing tungsten oxide and zinc oxide can be formed by a sputtering method using a target in which 0.5 to 5 wt % tungsten oxide and 0.1 to 1 wt % zinc oxide are added to indium oxide. Further, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), a nitride of a metal material (such as titanium nitride: TiN), or the like can be used. When the first electrode 101 or the second electrode 105 is formed as a light-transmitting electrode, the first electrode or the second electrode can be used as a light-transmitting electrode even with the use of a material having low transmittance of visible light by being formed to be approximately 1 to 50 nm thick, preferably approximately 5 to 20 nm thick. It is to be noted that a vacuum evaporation method, a CVD method, or a sol-gel method can also be used to manufacture the electrodes in addition to a sputtering method.

Since light-emission from the light-emitting layer 103 is extracted to an external portion through either the first electrode 101 or the second electrode 105, at least one of the first electrode 101 and the second electrode 105 is required to be formed using a light-transmitting material.

Subsequently, the light-emitting layer 103 will be explained. A material which forms the light-emitting layer according to the present invention contains at least a base material, a first impurity element, a second impurity element, and an organic compound.

As the base material contained in the light-emitting layer 103, an inorganic compound containing elements which belong to Groups 2 and 16 of the periodic table, or an inorganic compound containing elements which belong to Groups 12 and 16 of the periodic table can be used. For example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), zinc oxide (ZnO), yttrium oxide (Y₂O₃), aluminum nitride (AlN), gallium nitride (GaN), indium nitride (InN), zinc selenide (ZnSe), zinc telluride (ZnTe), zinc-gallium oxide (ZnGa₂O₄), strontium-gallium sulfide (SrGa₂S₄), barium-aluminum sulfide (BaAl₂S₄), barium-zinc sulfide (Ba₂ZnS₃), calcium-gallium sulfide (CaGa₂S₄), barium-silicon sulfide (BaSiS₄), calcium-aluminum sulfide (CaAl₂S₄), or the like can be used.

As the first impurity element contained in the light-emitting layer 103, copper (Cu), silver (Ag), gold (Au), platinum (Pt), arsenic (As), phosphorus (P), palladium (Pd), or the like can be used. Further, as the second impurity element, fluorine (F), chlorine (Cl), bromine (Br), iodine (I), boron (B), aluminum (Al), gallium (Ga), indium (In), thallium (Tl), or the like can be used.

In addition, as the organic compound contained in the light-emitting layer 103, a light-emitting organic compound with quantum efficiency of greater than or equal to 50% can be used. Either a fluorescent material or a phosphorescent material can be used as the light-emitting organic compound. For example, 2,5,8,11-tetra(tert-butyl)perylene (abbreviation: TBP); 4,4′-bis(2,2-diphenylvinyl)biphenyl (abbreviation: DPVBi); 3-(2-benzothiazolyl)-7-diethylaminocoumarin (abbreviation: coumarin 6); 5,6,11,12-tetraphenylnaphthacene (abbreviation: rubrene); dicyanomethylene-6-[p-(dimethylaminostyryl)-2-methyl-4H-pyran (abbreviation: DCM); bis[2-(4′,6′-difluorophenyl)pyridinato-N,C^{2′}](picolinato)iridium (abbreviation: FIrpic); tris(2-phenylpyridinato-N, C^{2′})iridium (abbreviation: Ir(ppy)₃); (acetylacetonato)bis(2-phenylpyridinato-N,C^{2′})iridium (abbreviation: Ir(ppy)₂(acac)); (acetylacetonato)bis(2-(2′-benzo[4,5-α]thienyl)pyridinato-N,C^{3′})iridium (abbreviation: Btp₂Ir(acac)), or the like can be used.

Further, a third impurity element can also be introduced to the light-emitting layer 103. In other words, the light-emitting layer 103 can contain at least the base material, the first impurity element, the second impurity element, the organic compound, and the third impurity element. As the third impurity element, manganese (Mn), lanthanoid (La), or the like can be used. As lanthanoid, for example, europium (Eu), neodymium (Nd), ytterbium (Yb), samarium (Sm), terbium (Tb), or the like can be used.

Subsequently, an example of a manufacturing method of the light-emitting element according to the present invention will be explained.

First, a manufacturing method of the light-emitting material contained in the light-emitting layer 103 will be explained. As described above, the light-emitting material which can be used for the light-emitting layer 103 according to the present invention contains a base material, a first impurity element, a second impurity element, and an organic compound. As a manufacturing method of the light-emitting material, various methods such as a solid-phase method and a liquid-phase method (a coprecipitation method) can be used. In addition, a liquid-phase method such as a spray pyrolysis method, a double decomposition method, a method by precursor pyrolysis, a reverse micelle method, a method in which the above method and high-temperature baking are combined, or a freeze-drying method can be used.

In the solid-phase method, the base material, the first impurity element, the second impurity element, the organic compound, and the like (hereinafter, the first impurity element, the second impurity element, and the organic compound are collectively referred to as an impurity element) are weighed, mixed in a mortar, and reacted with each other by heating and baking by an electric furnace so that the additive compound and the like are made to be contained in the base material. Baking temperatures are preferably 700 to 1500° C. This is because solid-phase reaction does not progress at a temperature that is too low and the base material is decomposed at a temperature that is too high. Baking may be performed to the base material and the impurity elements in a powder state; however, it is preferable to perform baking in a pellet state. This method requires baking at a temperature that is comparatively high but is simple; thus, this method has high productivity and is suitable for mass production.

In the liquid-phase method (coprecipitation method), the base material or a compound containing the base material and the impurity element or a compound containing the impurity element are reacted with each other in a solution and dried, and thereafter, they are baked. In this method, particles of the light-emitting material are uniformly dispersed, the particle has the small diameter, and reaction can progress even at a low baking temperature.

The additive amount of the first impurity element in the base material is not particularly limited. For example, the additive amount of the first impurity element in the base material is 0.01 to 10 mol %, preferably 0.05 to 5 mol %. In addition, the additive amount of the second impurity element in the base material is not particularly limited. For example, the additive amount of the second impurity element in the base material is 0.01 to 10 mol %, preferably 0.05 to 5 mol %. Further, the additive amount of the organic compound in the base material is not particularly limited. For example, the additive amount of the organic compound in the base material is 0.01 to 50 mol %, preferably 0.03 to 5 mol %.

In addition, as the light-emitting material contained in the light-emitting layer 103, the third impurity element may be introduced in addition to the base material, the first impurity element, the second impurity element, and the organic compound. In this case, the additive amount of the third impurity element is not particularly limited. For example, the additive amount of the third impurity element in the base material is 0.01 to 10 mol %, preferably 0.05 to 5 mol %.

The light-emitting layer 103 can be formed using the above-described light-emitting materials by a vacuum evaporation method such as a resistance heating evaporation method or an electron beam evaporation (EB evaporation) method, a physical vapor deposition (PVD) method such as a sputtering method, a chemical vapor deposition (CVD) method such as a metal organic CVD method, a plasma CVD method, a thermal CVD method, or a low-pressure hydride transport CVD method, an atomic layer epitaxy (ALE) method, an ink-jet method, a spin coating method, a spray method, a screen printing method, or the like.

In addition, the light-emitting layer 103 can be formed by combination of different methods in order to disperse the first impurity element, the second impurity element, and the organic compound in the base material. For example, electron beam evaporation (EB evaporation) is performed using pellets obtained by baking the base material and the first impurity element as a target while the second impurity element is evaporated by another electron beam, and the organic compound is evaporated by resistance heating evaporation, whereby the light-emitting layer 103 can be obtained.

It is to be noted that a thickness of the light-emitting layer is not particularly limited, but is preferably in the range of 1 nm to 1 mm, much preferably 10 nm to 500 μm.

Alternatively, the light-emitting material that can be used for the light-emitting layer 103 according to the present invention is processed into a particle state and dispersed in a binder to form the light-emitting layer 103 having a film shape. When a particle having a sufficiently desired size cannot be obtained by a manufacturing method of the light-emitting material, the light-emitting material may be crushed in a mortar or the like and processed into a particle state. The binder is a substance for fixing particles of the light-emitting material in a dispersed state and keeping a shape as the light-emitting layer 103. The light-emitting material is uniformly dispersed and fixed in the light-emitting layer 103 by the binder.

The light-emitting layer 103 in this case can be formed by a droplet-discharging method which can selectively form a light-emitting layer, a printing method (screen printing, offset printing, or the like), a coating method such as a spin coating method, a dipping method, a dispenser method, or the like. The thickness is not particularly limited, but is preferably in the range of 10 to 1000 nm. Further, in the light-emitting layer containing the light-emitting material and the binder, the ratio of the light-emitting material is preferably greater than or equal to 50 wt % and less than or equal to 80 wt %.

As a binder that can be used in this embodiment mode, an organic material, an inorganic material, or a mixed material of an organic material and an inorganic material can be used. As an organic material, the following resin materials can be used: a polymer having a comparatively high dielectric constant such as a cyanoethyl cellulose based resin, polyethylene, polypropylene, a polystyrene based resin, a silicone resin, an epoxy resin, vinylidene fluoride, and the like. In addition, a heat-resistant high-molecular material such as aromatic polyamide or polybenzimidazole, or a siloxane resin may also be used. The siloxane resin is a resin including a Si—O—Si bond. Siloxane has a skeleton structure formed of a bond of silicon (Si) and oxygen (O). As a substituent, an organic group containing at least hydrogen (for example, an alkyl group or aromatic hydrocarbon) is used. Alternatively, a fluoro group may be used as a substituent. In addition, as a substituent, both a fluoro group and an organic group containing at least hydrogen may also be used. Further, the following resin materials may also be used: a vinyl resin such as polyvinyl alcohol or polyvinylbutyral, a phenol resin, a novolac resin, an acrylic resin, a melamine resin, an urethane resin, an oxazole resin (polybenzoxazole), and the like. In addition, for example, a photo-curable resin or the like can be used. Fine particles having a high dielectric constant such as barium titanate (BaTiO₃) or strontium titanate (SrTiO₃) can also be mixed to these resins moderately to adjust a dielectric constant.

As an inorganic material contained in the binder, a material such as silicon oxide (SiOₓ), silicon nitride (SiNₓ), silicon containing oxygen and nitrogen, aluminum nitride (AlN), aluminum containing oxygen and nitrogen, aluminum oxide (Al₂O₃), titanium oxide (TiO₂), BaTiO₃, SrTiO₃, lead titanate (PbTiO₃), potassium niobate (KNbO₃), lead niobate (PbNbO₃), tantalum oxide (Ta₂O₅), barium tantalate (BaTa₂O₆), lithium tantalate (LiTaO₃), yttrium oxide (Y₂O₃), zirconium oxide (ZrO₂), ZnS, or other substances containing an inorganic material can be used. When an inorganic material having a high dielectric constant is made to be contained in the organic material (by addition or the like), a dielectric constant of the light-emitting layer formed of the light-emitting material and the binder can be more effectively controlled and can be much higher.

In the manufacturing process, the light-emitting material is dispersed in a solution containing a binder. As a solvent of the solution containing a binder that can be used in this embodiment mode, a solvent which can form a solution having viscosity, which can dissolve a binder material and is suitable for a method for forming the light-emitting layer (various wet processes) and a desired thickness, may be appropriately selected. An organic solvent or the like can be used, and when, for example, a siloxane resin is used as a binder, propylene glycol monomethyl ether, propylene glycol monomethyl ether acetate (also referred to as PGMEA), 3-methoxy-3-methyl-1-butanol (also referred to as MMB), or the like can be used.

Next, an estimated mechanism of light-emission in the light-emitting element of the present invention will be explained. The light-emitting element of the present invention includes a light-emitting layer between a pair of electrodes, and the light-emitting layer contains at least a base material, a first impurity element, a second impurity element, and an organic compound. In the light-emitting element of the present invention, transition energy is obtained by recombination transition between a donor-acceptor pair (hereinafter referred to as a D-A pair) performed by two impurity elements (the first impurity element and the second impurity element) contained in the light-emitting layer. This energy is transmitted to the organic compound, whereby the organic compound is excited. Then, when the excited organic compound returns to the ground state, fluorescence or phosphorescence is emitted, which is considered to lead light-emission.

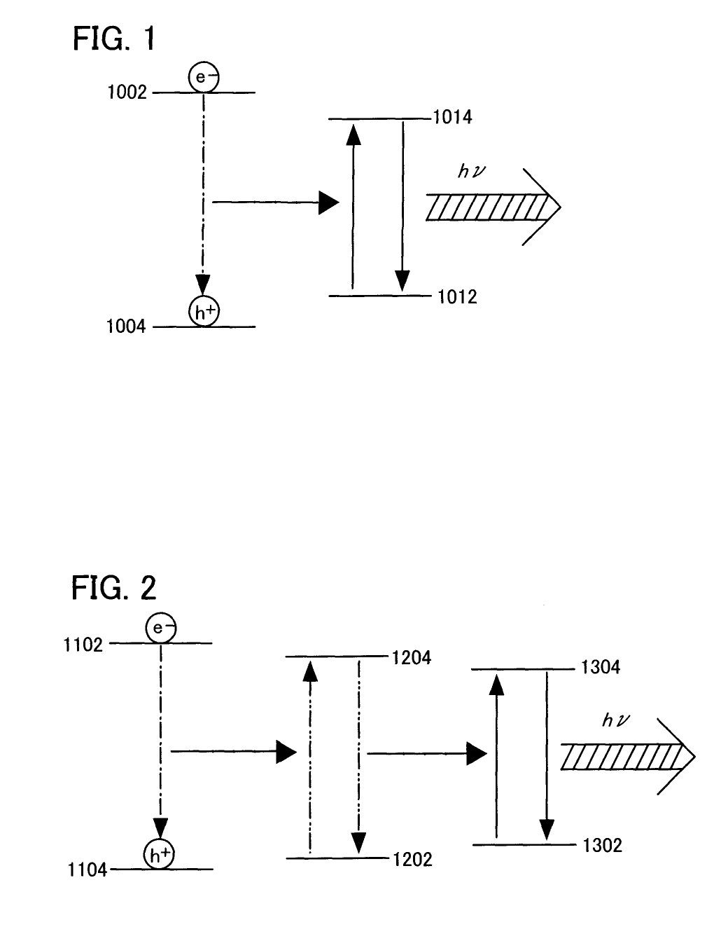

It is considered that there are two kinds of energy transition. FIGS. 1 and 2 show schematic views of two kinds of energy transition, which will be explained below.

In FIG. 1, transition energy between a D-A pair is directly transmitted to an organic compound. FIG. 1 shows a first impurity level 1002 and a second impurity level 1004 which originate from two impurity elements (a first impurity element and a second impurity element). In addition, a ground state 1012 and an excited state 1014 of the organic compound are shown.

In FIG. 1, in the light-emitting element, an electron in the first impurity level 1002 and a hole in the second impurity level 1004, which originate from two impurity elements (the first impurity element and the second impurity element), are recombined; thus, transition energy is generated. Next, the generated transition energy is transmitted to the organic compound, and the organic compound is excited from the ground state 1012 to the excited state 1014. Then, the organic compound returns from the excited state 1014 to the ground state 1012, whereby light-emission can be obtained.

In FIG. 2, transition energy between a D-A pair is transmitted to a third impurity element, the third impurity element is excited once, and its excitation energy is transmitted to an organic compound. FIG. 2 shows a first impurity level 1102 and a second impurity level 1104 which originate from two impurity elements (a first impurity element and a second impurity element). In addition, a ground state 1202 and an excited state 1204 which originate from the third impurity element, and a ground state 1302 and an excited state 1304 which originate from the organic compound are shown.

In FIG. 2, in the light-emitting element, an electron in the first impurity level 1102 and a hole in the second impurity level 1104, which originate from two impurity elements (the first impurity element and the second impurity element), are recombined; thus, transition energy is generated, similarly to FIG. 1. Next, the generated transition energy is transmitted to the third impurity element, and the third impurity element is excited from the ground state 1202 to the excited state 1204. Then, when the excited emission center returns from the excited state 1204 to the ground state 1202, excitation energy is generated. This excitation energy is transmitted to the organic compound, and the organic compound is excited from the ground state 1302 to the excited state 1304. The organic compound returns from the excited state 1304 to the ground state 1302, whereby light-emission can be obtained.

As described with reference to FIGS. 1 and 2, it is considered that the organic compound emits light in either energy transition. Therefore, quantum efficiency of an inorganic compound does not influence element characteristics, and an element with high light-emitting efficiency can be obtained.

In addition, in either energy transition shown in FIG. 1 or 2, the organic compound does not influence transition of an electron and a hole. Therefore, the organic compound does not become an anion radical or a cation radical. It has been reported that tris(8-quinolinolato)aluminum (abbreviation: Alq₃) that is a typical organic EL element material becomes a cation radical and therefore deteriorates. However, the organic compound contained in the light-emitting layer according to the present invention does not become an anion radical or a cation radical; therefore, a highly reliable element can be manufactured.

In addition, in the case of an inorganic EL element, a color of light-emission from the light-emitting material is strongly influenced by a crystalline field of a base material. However, it is considered that the organic compound emits light in the light-emitting element according to the present invention. In general, the organic compound is not easily influenced by an atmosphere; thus, a color of light-emission in the light-emitting element depends on the kind of the organic compound. Accordingly, by appropriate selection of the organic compounds of infinite kinds, light-emission of various colors can be obtained.

The light-emitting element of the present invention can be driven by voltage application to two electrodes. When voltage is applied to the element, excited species are generated in an impurity level originating from an impurity element added to a base material. The generated excited species transmit energy to a fluorescent organic material or a phosphorescent organic material added to the base material directly or through a third impurity element added to the base material, whereby the organic material is excited and the organic material in an excited state emits fluorescence or phosphorescence. Therefore, the element functions as a light-emitting element.

In the present invention, since an organic material with high quantum efficiency is used, light can be emitted with high efficiency. It is to be noted that AC voltage, DC voltage, or pulsed voltage may be applied to two electrodes of the light-emitting element.

In the light-emitting element of the present invention obtained as described above, electric energy can be efficiently converted to light; thus, intended luminance can be obtained with much less electric power. In addition, chromaticity can be easily adjusted through selection of a fluorescent organic material or a phosphorescent organic material to be combined. Further, since excited molecules are generated without becoming organic molecules in a radical cation state or radical anion state, reliability of the element can be enhanced.

### Embodiment Mode 2

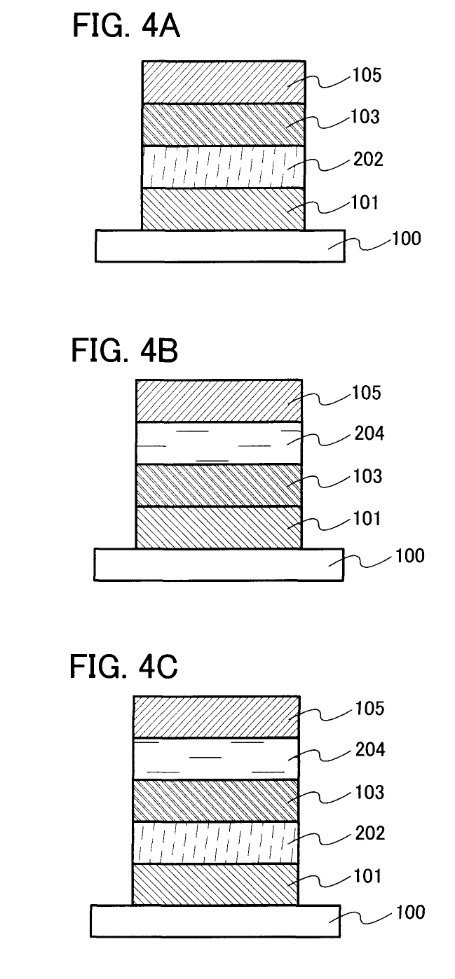

Subsequently, a light-emitting element according to the present invention will be explained with reference to FIGS. 4A to 4C. This embodiment mode will explain a structure in which a light-emitting element includes an insulating layer. A structure, a manufacturing method, and the like of components other than the insulating layer are based on Embodiment Mode 1, and explanation thereof will thus be omitted.

The light-emitting element shown in this embodiment mode has an element structure including, over a substrate 100, a first electrode 101, a second electrode 105, and a light-emitting layer 103 between the first electrode and the second electrode. In addition, either a first insulating layer 202 between the first electrode 101 and the light-emitting layer 103 or a second insulating layer 204 between the light-emitting layer 103 and the second electrode 105, or both of them are provided.

FIG. 4A shows a light-emitting element having a structure in which, over a substrate 100, a first electrode 101, an insulating layer (first insulating layer) 202, a light-emitting layer 103, and a second electrode 105 are sequentially stacked. In addition, FIG. 4B shows a light-emitting element having a structure in which, over a substrate 100, a first electrode 101, a light-emitting layer 103, an insulating layer (second insulating layer) 204, and a second electrode 105 are sequentially stacked. Further, FIG. 4C shows a light-emitting element having a structure in which, over a substrate 100, a first electrode 101, a first insulating layer 202, a light-emitting layer 103, a second insulating layer 204, and a second electrode 105 are sequentially stacked.

A material for forming the first insulating layer 202 and the second insulating layer 204 is not particularly limited, but preferably has high withstand voltage and dense film quality. Further, the material preferably has a high dielectric constant. For example, a material such as silicon oxide (SiOₓ), silicon nitride (SiNₓ), silicon oxynitride, silicon nitride oxide, aluminum nitride (AlN), aluminum oxynitride (AlON), aluminum nitride oxide (AlNO), aluminum oxide (Al₂O₃), titanium oxide (TiO₂), BaTiO₃, SrTiO₃, lead titanate (PbTiO₃), potassium niobate (KNbO₃), lead niobate (PbNbO₃), Ta₂O₅, barium tantalate (BaTa₂O₆), lithium tantalate (LiTaO₃), yttrium oxide (Y₂O₃), zirconium oxide (ZrO₂), or other substances containing an inorganic insulating material can be used. When the first insulating layer 202 or the second insulating layer 204 is formed by an inorganic material having a high dielectric constant, which is made to be contained in the organic material (by addition or the like), a dielectric constant of the light-emitting layer 103 formed of the light-emitting material and the binder can be more effectively controlled and can be much higher.

The light-emitting element of the present invention can be driven by voltage application to two electrodes. When voltage is applied to the element, excited species are generated in an impurity level originating from an impurity element added to a base material. The generated excited species transmit energy to a fluorescent organic material or a phosphorescent organic material added to the base material directly or through a third impurity element added to the base material, whereby the organic material is excited and the organic material in an excited state emits fluorescence or phosphorescence. Therefore, the element functions as a light-emitting element.

In the present invention, since an organic material with high quantum efficiency is used, light can be emitted with high efficiency. It is to be noted that AC voltage, DC voltage, or pulsed voltage may be applied to two electrodes of the light-emitting element.

### Embodiment Mode 3

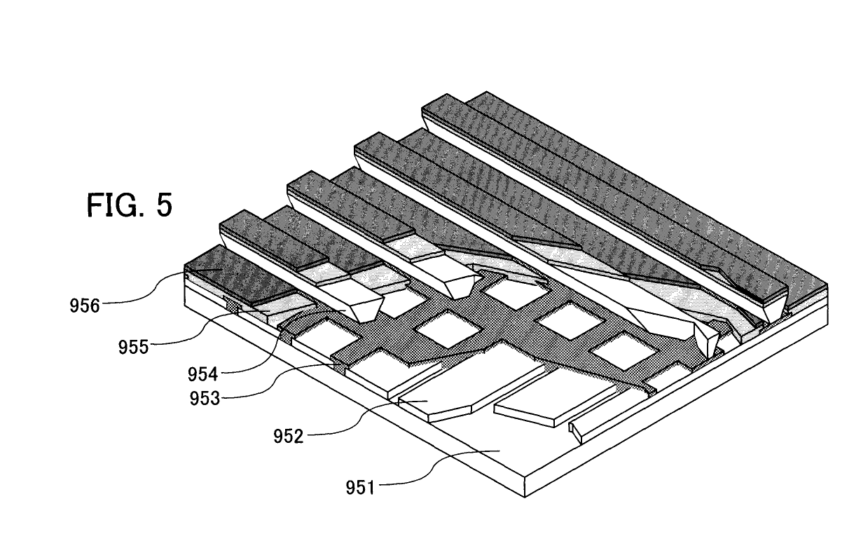

This embodiment mode will explain a light-emitting device including the light-emitting element of the present invention with reference to FIG. 5.

The light-emitting device shown in this embodiment mode is a passive type light-emitting device which drives the light-emitting element without providing a driving element such as a transistor. FIG. 5 is a perspective view of a passive type light-emitting device manufactured by employing the present invention.

In FIG. 5, a layer 955 is provided between electrodes 952 and 956 over a substrate 951. It is to be noted that the layer 955 includes the light-emitting layer shown in Embodiment Mode 1, or the light-emitting layer and the insulating layer shown in Embodiment Mode 2. When the layer 955 has an insulating layer, an insulating layer may be provided both or either between the electrode 952 and the light-emitting layer and/or between the electrode 956 and the light-emitting layer.

The edge of the electrode 952 is covered with an insulating layer 953. Further, a partition layer 954 is provided over the insulating layer 953. The side wall of the partition layer 954 slopes so that a distance between one side wall and the other side wall becomes narrow toward the substrate surface. In other words, a cross section of the partition layer 954 in a short side direction is trapezoidal, and the base (a side facing the same direction as a plane direction of the insulating layer 953 and being in contact with the insulating layer 953) is shorter than the upper side (a side facing the same direction as the plane direction of the insulating layer 953 and not being in contact with the insulating layer 953). By providing the partition layer 954 in this manner, defects of the light-emitting element due to static electricity or the like can be prevented.

As in this embodiment mode, when the light-emitting element of the present invention which emits light efficiently is included, a passive type light-emitting device which can be driven with low power consumption can be obtained. In addition, a highly reliable light-emitting device which can display various colors clearly can be obtained.

### Embodiment Mode 4

This embodiment mode will explain a light-emitting device including the light-emitting element of the present invention.

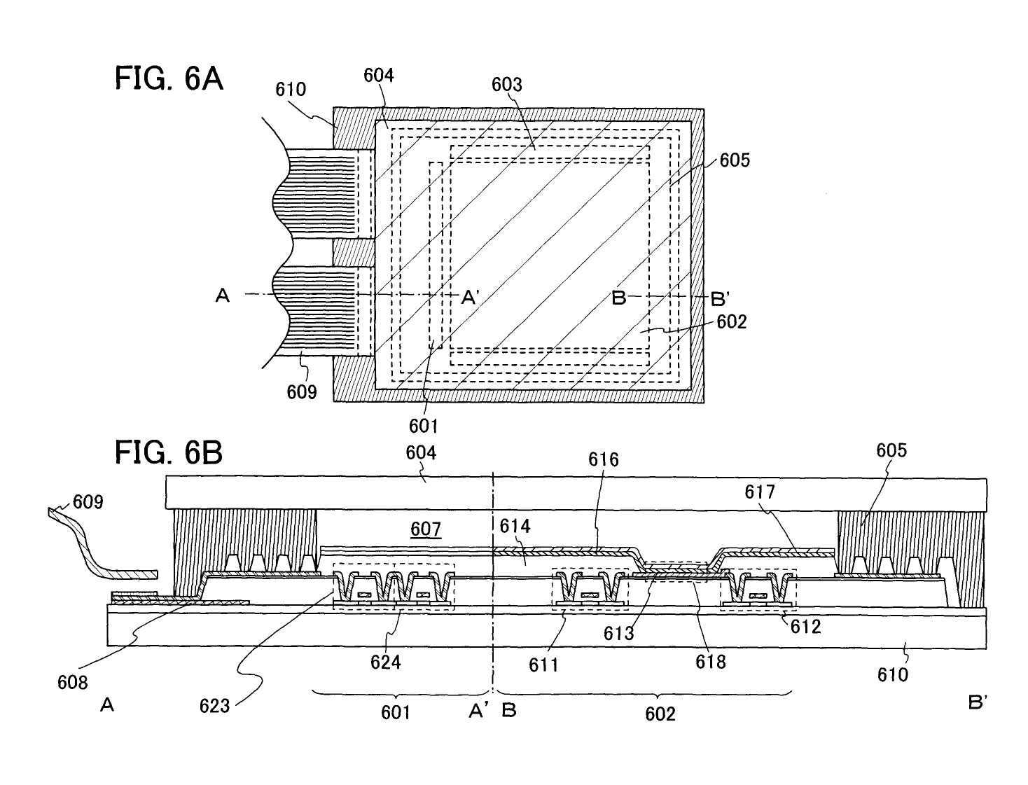

This embodiment mode will explain an active type light-emitting device in which driving of a light-emitting element is controlled by a transistor. This embodiment mode will explain a light-emitting device including the light-emitting element of the present invention in a pixel portion with reference to FIGS. 6A and 6B. It is to be noted that FIG. 6A is a top view showing a light-emitting device, and FIG. 6B is a cross-sectional view of FIG. 6A taken along lines A-A′ and B-B′. Reference numeral 601 denotes a driver circuit portion (source side driver circuit); 602, a pixel portion; and 603, a driver circuit portion (gate side driver circuit), which are indicated by dotted lines. Reference numeral 604 denotes a sealing substrate; 605, a sealing material; and a portion surrounded by the sealing material 605 corresponds to a space 607.

It is to be noted that a lead wiring 608 is a wiring for transmitting a signal to be input to the source side driver circuit 601 and the gate side driver circuit 603 and receives a video signal, a clock signal, a start signal, a reset signal, and the like from an FPC (flexible printed circuit) 609 that is an external input terminal. It is to be noted that only the FPC is shown here; however, the FPC may be provided with a printed wiring board (PWB). The light-emitting device in this specification includes not only a light-emitting device itself but also a light-emitting device provided with an FPC or a PWB.

Subsequently, a cross-sectional structure will be explained with reference to FIG. 6B. The driver circuit portion and the pixel portion are formed over an element substrate 610. Here, the source side driver circuit 601 which is the driver circuit portion and one pixel in the pixel portion 602 are shown.

It is to be noted that a CMOS circuit, which is a combination of an n-channel TFT 623 and a p-channel TFT 624, is formed as the source side driver circuit 601. A TFT for forming the driver circuit may be formed using a known circuit such as a CMOS circuit, a PMOS circuit, or an NMOS circuit. Although a driver integration type in which a driver circuit is formed over a substrate is shown in this embodiment mode, a driver circuit is not necessarily formed over a substrate and can be formed in an external portion.

The pixel portion 602 has a plurality of pixels, each of which includes a switching TFT 611, a current control TFT 612, and a first electrode 613 which is electrically connected to a drain of the current control TFT 612. It is to be noted that an insulator 614 is formed so as to cover the edge of the first electrode 613. Here, a positive photosensitive acrylic resin film is used for the insulator 614.

The insulator 614 is formed so as to have a curved surface having curvature at an upper edge or a lower edge thereof in order to make the coverage favorable. For example, in the case where positive photosensitive acrylic is used as a material for the insulator 614, the insulator 614 is preferably formed so as to have a curved surface with a curvature radius (0.2 to 3 μm) only at the upper edge thereof. Either a negative type material which becomes insoluble in an etchant by light irradiation or a positive type material which becomes soluble in an etchant by light irradiation can be used as the insulator 614.

A layer 616 and a second electrode 617 are formed over the first electrode 613. The layer 616 includes the light-emitting layer shown in Embodiment Mode 1, or the light-emitting layer and the insulating layer shown in Embodiment Mode 2. In addition, at least one of the first electrode 613 and the second electrode 617 has a light-transmitting property, and light-emission from the layer 616 can be extracted to an external portion.

The first electrode 613, the layer 616, and the second electrode 617 are formed by various methods. Specifically, a vacuum evaporation method such as a resistance heating evaporation method or an electron beam evaporation (EB evaporation) method, a physical vapor deposition (PVD) method such as a sputtering method, a chemical vapor deposition (CVD) method such as a metal organic CVD method or a low-pressure hydride transport CVD method, an atomic layer epitaxy (ALE) method, or the like can be used. In addition, an ink-jet method, a spin coating method, or the like may be used. Each electrode or each layer can be formed by a different deposition method. In this embodiment mode, the first electrode 613, the layer 616, and the second electrode 617 form a light-emitting element 618.

The sealing substrate 604 and the element substrate 610 are attached to each other with the sealing material 605, whereby the light-emitting element 618 is provided in the space 607 surrounded by the element substrate 610, the sealing substrate 604, and the sealing material 605. It is to be noted that the space 607 is filled with a filler. There is also the case where the space 607 is filled with the sealing material 605 as well as an inert gas (nitrogen, argon, or the like).

It is to be noted that an epoxy-based resin is preferably used as the sealing material 605. Preferably, the material allows as little moisture and oxygen as possible to penetrate therethrough. As the sealing substrate 604, a plastic substrate made of FRP (Fiberglass-Reinforced Plastics), PVF (polyvinyl fluoride), Myler, polyester, acrylic, or the like can be used, besides a glass substrate or a quartz substrate.

In such a manner, a light-emitting device including the light-emitting element of the present invention can be obtained.

As in this embodiment mode, high light-emitting efficiency can be realized through the use of the light-emitting element of the present invention using an organic material with high quantum efficiency. Therefore, an active type light-emitting device which can be driven with low power consumption can be obtained. In addition, a highly reliable light-emitting device which can display various colors clearly can be obtained.

### Embodiment Mode 5

This embodiment mode will explain an electronic device of the present invention which includes the light-emitting device shown in Embodiment Mode 3 or 4 in part thereof.

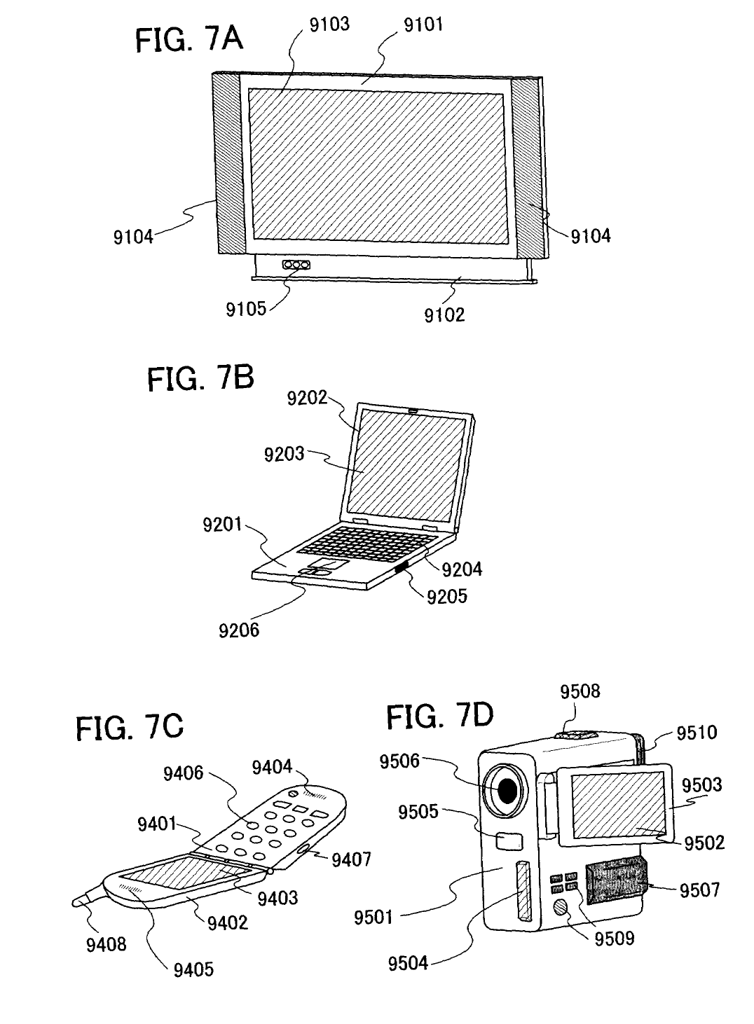

As an electronic device which is manufactured by using the light-emitting element of the present invention, a camera such as a video camera or a digital camera, a goggle type display, a navigation system, an audio reproducing device (a car audio stereo, an audio component stereo, or the like), a computer, a game machine, a portable information terminal (a mobile computer, a mobile phone, a portable game machine, an electronic book, or the like), an image reproducing device provided with a recording medium (specifically, a device capable of reproducing a recording medium such as a Digital Versatile Disc (DVD) and provided with a display device that can display the image), and the like are given. Specific examples of these electronic devices are shown in FIGS. 7A to 7D.

FIG. 7A shows a television device according to the present invention, which includes a housing 9101, a supporting base 9102, a display portion 9103, a speaker portion 9104, a video input terminal 9105, and the like. In the television device, the display portion 9103 has light-emitting elements similar to those explained in Embodiment Mode 1 or 2, which are arranged in a matrix. One feature of the light-emitting element is that light-emitting efficiency is high and power consumption is low. The display portion 9103 which includes the light-emitting elements has a similar feature. Therefore, in the television device, power consumption can be reduced. Further, it is easy to adjust chromaticity; therefore, light of various colors can be clearly emitted. With such a feature, a deterioration compensation function can be significantly reduced or downsized in the television device; therefore, small size and lightweight housing 9101 and supporting base 9102 can be achieved. In the television device according to the present invention, low power consumption, high image quality, and a small size and lightweight are achieved; therefore, a product which is suitable for living environment can be provided.

FIG. 7B shows a computer according to the present invention, which includes a main body 9201, a housing 9202, a display portion 9203, a keyboard 9204, an external connection port 9205, a pointing mouse 9206, and the like. In the computer, the display portion 9203 has light-emitting elements similar to those explained in Embodiment Mode 1 or 2, which are arranged in a matrix. One feature of the light-emitting element is that light-emitting efficiency is high and power consumption is low. Further, it is easy to adjust chromaticity; therefore, light of various colors can be clearly emitted. The display portion 9203 which includes the light-emitting elements has a similar feature. Therefore, in the computer, deterioration in image quality is reduced and lower power consumption is achieved. With such a feature, a deterioration compensation function can be significantly reduced or downsized in the computer; therefore, small size and lightweight main body 9201 and housing 9202 can be achieved. In the computer according to the present invention, low power consumption, high image quality, and a small size and lightweight are achieved; therefore, a product which is suitable for living environment can be provided.

FIG. 7C shows a mobile phone according to the present invention, which includes a main body 9401, a housing 9402, a display portion 9403, an audio input portion 9404, an audio output portion 9405, an operation key 9406, an external connection port 9407, an antenna 9408, and the like. In the mobile phone, the display portion 9403 has light-emitting elements similar to those explained in Embodiment Mode 1 or 2, which are arranged in a matrix. One feature of the light-emitting element is that light-emitting efficiency is high and power consumption is low. Further, it is easy to adjust chromaticity; therefore, light of various colors can be clearly emitted. The display portion 9403 which includes the light-emitting elements has a similar feature. Therefore, in the mobile phone, deterioration in image quality is reduced and lower power consumption is achieved. With such a feature, a deterioration compensation function can be significantly reduced or downsized in the mobile phone; therefore, small size and lightweight main body 9401 and housing 9402 can be achieved. In the mobile phone according to the present invention, low power consumption, high image quality, and a small size and lightweight are achieved; therefore, a product which is suitable for carrying can be provided.

FIG. 7D shows a camera according to the present invention, which includes a main body 9501, a display portion 9502, a housing 9503, an external connection port 9504, a remote control receiving portion 9505, an image receiving portion 9506, a battery 9507, an audio input portion 9508, operation keys 9509, an eye piece portion 9510, and the like. In the camera, the display portion 9502 has light-emitting elements similar to those explained in Embodiment Mode 1 or 2, which are arranged in a matrix. One feature of the light-emitting element is that light-emitting efficiency is high and power consumption is low. Further, it is easy to adjust chromaticity; therefore, light of various colors can be clearly emitted. The display portion 9502 which includes the light-emitting elements has a similar feature. Therefore, in the camera, deterioration in image quality is reduced and lower power consumption is achieved. With such a feature, a deterioration compensation function can be significantly reduced or downsized in the camera; therefore, a small size and lightweight main body 9501 can be achieved. In the camera according to the present invention, low power consumption, high image quality, and a small size and lightweight are achieved; therefore, a product which is suitable for carrying can be provided.

As described above, the applicable range of the light-emitting device of the present invention is so wide that the light-emitting device can be applied to electronic devices in various fields. Through the use of the light-emitting device of the present invention, electronic devices which have display portions consuming low power and having high image quality and high reliability can be provided.

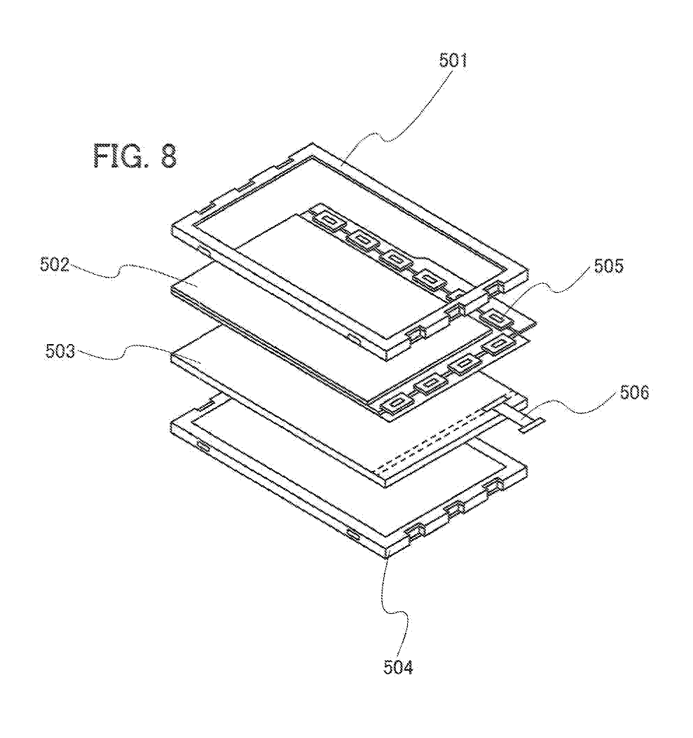

The light-emitting device of the present invention includes a light-emitting element with high light-emitting efficiency and can also be used as a lighting system. One mode using the light-emitting element of the present invention as the lighting system will be explained with reference to FIG. 8.

FIG. 8 shows an example of a liquid crystal display device using the light-emitting device of the present invention as a backlight. The liquid crystal display device shown in FIG. 8 includes a housing 501, a liquid crystal layer 502, a backlight 503, and a housing 504, and the liquid crystal layer 502 is connected to a driver IC 505. The light-emitting device of the present invention is used for the backlight 503, and current is supplied through a terminal 506.

Through the use of the light-emitting device of the present invention as the backlight of the liquid crystal display device, a backlight with reduced power consumption can be obtained. The light-emitting device of the present invention is a lighting system with plane light-emission, and can have a large area. Therefore, the backlight can have a large area, and a liquid crystal display device having a large area can be obtained. Furthermore, the light-emitting device has a thin shape and consumes low power; therefore, a thin shape and low power consumption of the display device can also be achieved.

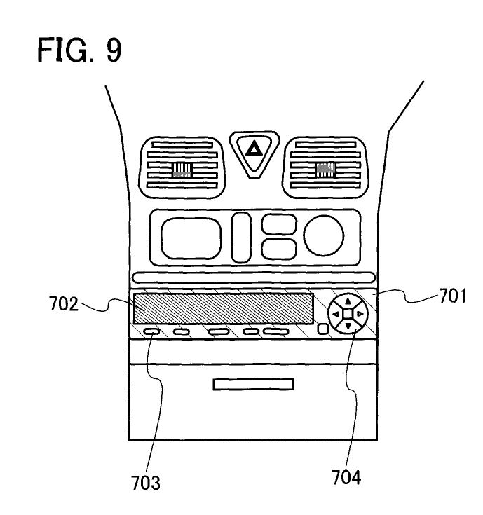

FIG. 9 is an audio reproducing device, specifically, a car audio stereo, which includes a main body 701, a display portion 702, and operation switches 703 and 704. The display portion 702 can be obtained through the use of the light-emitting device of Embodiment Mode 3 (passive type) or the light-emitting device of Embodiment Mode 4 (active type). Further, the display portion 702 may be formed using a segment type light-emitting device. In any case, through the use of the light-emitting element according to the present invention, a display portion having high image quality and high reliability can be formed in which a vehicular power source (12 to 42 V) is used to achieve low power consumption. In addition, although this embodiment mode shows a car audio stereo, the light-emitting element of the present invention can also be used for a portable or home audio stereo.

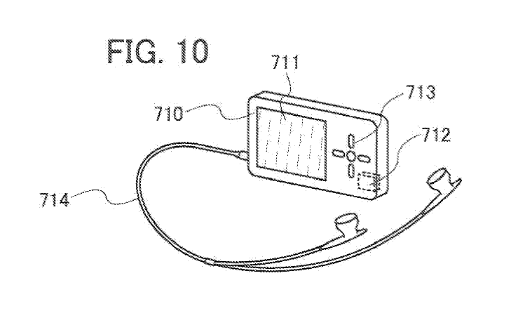

FIG. 10 shows a digital player as an example of the above. The digital player shown in FIG. 10 includes a main body 710, a display portion 711, a memory portion 712, an operation portion 713, an earphone 714, and the like. A headphone or a wireless earphone can be used instead of the earphone 714. The display portion 711 can be obtained through the use of the light-emitting device of Embodiment Mode 3 (passive type) or the light-emitting device of Embodiment Mode 4 (active type). Further, the display portion 711 may be formed using a segment type light-emitting device. In any case, through the use of the light-emitting element according to the present invention, a display portion having high image quality and high reliability can be formed, which can perform display even with the use of a secondary battery (nickel-hydrogen battery or the like) to achieve low power consumption. A hard disk or a nonvolatile memory is used for the memory portion 712. For example, the operation portion 713 is operated with the use of a NAND type nonvolatile memory having a memory capacity of 20 to 200 gigabytes, and thus, image or sound (music) can be recorded or reproduced. It is to be noted that power consumption of the display portions 702 and 711 can be suppressed through display of white characters on the black background. This is particularly effective in a portable audio device.

As described above, the applicable range of the light-emitting device manufactured by employing the present invention is so wide that the light-emitting device can be applied to electronic devices in various fields. By employing the present invention, electronic devices which have display portions consuming low power and having high image quality and high reliability can be manufactured.

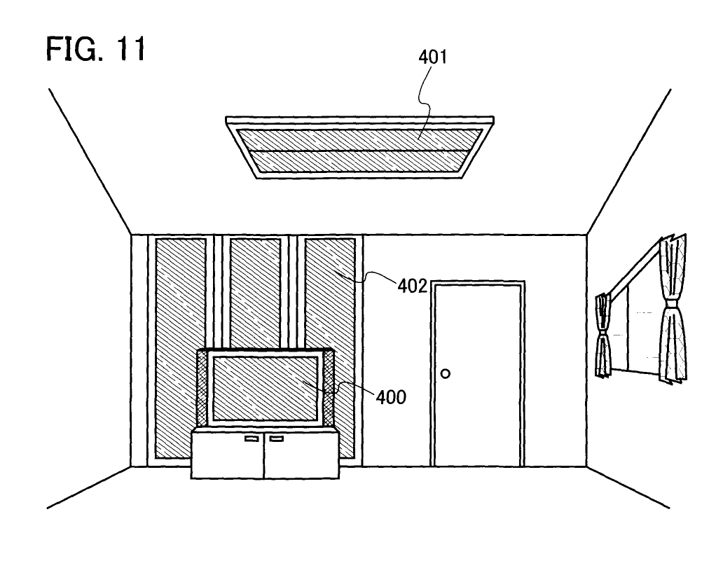

FIG. 11 is an example in which the light-emitting device employing the present invention is used as each of interior lighting systems 401 and 402. The lighting system 401 is fixed to a ceiling, and the lighting system 402 is embedded in a wall. Since the light-emitting device of the present invention can have a large area, a large-area lighting system can be obtained. In addition, the light-emitting device of the present invention has a thin shape and consumes low power; therefore, a thin-shape and low power consumption of the lighting system can be obtained. Public broadcasting and a movie can be appreciated when a television device 400 according to the present invention as explained in FIG. 7A is set in a room where the light-emitting device employing the present invention is used as the interior lighting system 401. In such a case, both devices consume low power so that a dynamic image can be appreciated in a bright room without concerns about electricity costs.

The lighting system is not limited to the one described in this embodiment mode, and the light-emitting device of the present invention can be applied to various types of lighting system, such as a lighting system for a house or public facilities. In such a case, in the lighting system according to the present invention, a light-emitting medium has a thin-film shape; therefore, a degree of freedom in design is high. Accordingly, various fancy products can be provided to the market.

### Embodiment 1

A light-emitting element of the present invention was manufactured, and characteristics thereof were examined.

Over a glass substrate, indium tin oxide containing silicon oxide was formed as a first electrode. Then, a cyano resin and coumarin 6 were dissolved in dimethylformamide (DMF), ZnS, Cu, and Cl were dispersed therein, and this mixture was applied on the first electrode, whereby a light-emitting layer was formed. Next, a cyano resin and BaTiO₃ were dispersed in DMF and applied on the light-emitting layer, whereby an insulating layer was formed. Thereafter, Ag was deposited, whereby a second electrode was formed over the insulating layer. It is to be noted that a light-emitting element containing ZnS, Cu, Cl, and coumarin 6 at a weight ratio of 1:0.03 (ZnS, Cu, and Cl:coumarin 6) is to be a light-emitting element 1, a light-emitting element containing ZnS, Cu, Cl, and coumarin 6 at a weight ratio of 1:0.01 (ZnS, Cu, and Cl:coumarin 6) is to be a light-emitting element 2, and a light-emitting element not containing coumarin 6 is to be a comparative light-emitting element 1.

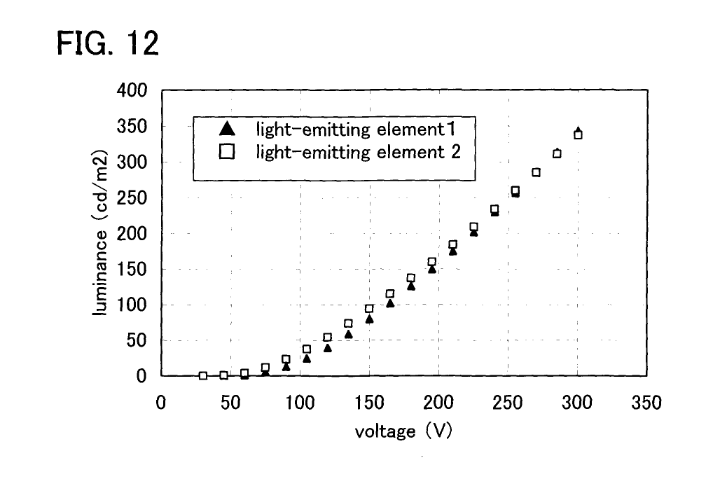

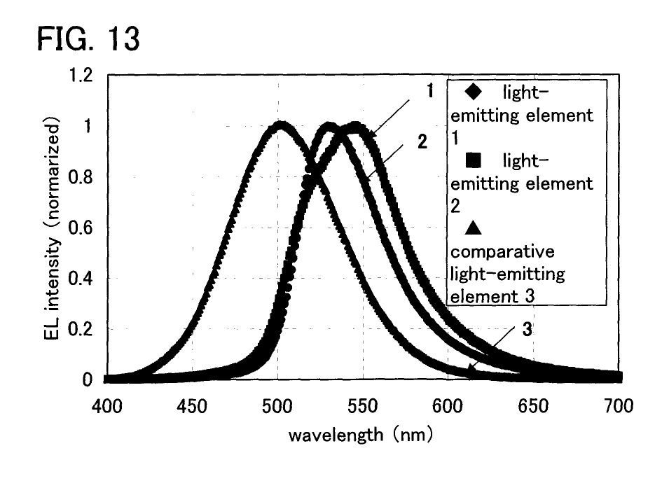

FIGS. 12 and 13 show element characteristics of the light-emitting elements 1 and 2 which were manufactured as described above.

FIG. 12 shows voltage-luminance characteristics of the light-emitting elements manufactured in this embodiment. In FIG. 12, a horizontal axis represents applied voltage (V) and a vertical axis represents luminance (cd/m²). Plotting shows the light-emitting element 1, and the light-emitting element 2. According to FIG. 12, it was found that, in the light-emitting elements 1 and 2, luminance scarcely changes even when the amount of coumarin 6 contained in the light-emitting layer is increased.

FIG. 13 shows electroluminescence (EL) spectra (measurement frequency: f=1[kHz]). It is to be noted that each emission intensity is standardized in FIG. 13. According to FIG. 13, it was found that light-emission originates from Cu and Cl in the comparative light-emitting element 3 since it has a peak of the emission spectrum around 500 nm. On the other hand, it was found that light-emission originates from coumarin 6 in the light-emitting elements 1 and 2 since they have a peak of the emission spectrum around 550 nm. The light-emitting elements 1 and 2 each contain Cu as a first impurity element, Cl as a second impurity element, and coumarin 6 as an organic compound. It was found that, in the light-emitting elements 1 and 2, light-emission originating from Cu and Cl was not observed, only light-emission originating from coumarin 6 that is an organic compound was observed, and energy transition from the impurity element to the organic compound was caused efficiently.

This application is based on Japanese Patent Application serial No. 2006-058744 filed in Japan Patent Office on Mar. 3, 2006, the entire contents of which are hereby incorporated by reference.

What is claimed is:

1. A light-emitting element comprising:
a first electrode;
a second electrode; and
a light-emitting layer between the first electrode and the second electrode,
wherein the light-emitting layer includes a base material, a first impurity element, a second impurity element, and an organic compound,
wherein the base material is an inorganic compound including an element belonging to Group 2 of the periodic table and an element belonging to Group 16 of the periodic table, or an inorganic compound including an element belonging to Group 12 of the periodic table and an element belonging to Group 16 of the periodic table,
wherein the first impurity element is at least one of copper (Cu), silver (Ag), gold (Au), platinum (Pt), arsenic (As), phosphorus (P), and palladium (Pd), and
wherein the second impurity element is at least one of fluorine (F), chlorine (Cl), bromine (Br), iodine (I), boron (B), aluminum (Al), gallium (Ga), indium (In), and thallium (Tl).

2. The light-emitting element according to claim 1, wherein the base material is selected from a group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, zinc-gallium oxide, strontium-gallium sulfide, barium-aluminum sulfide, barium-zinc sulfide, calcium-gallium sulfide, barium-silicon sulfide, and calcium aluminum sulfide.

3. A light-emitting device comprising the light-emitting element according to claim 1.

4. An electronic device comprising the light-emitting device according to claim 3 in a display portion.

5. A light-emitting element comprising:
a first electrode;
a second electrode; and
a light-emitting layer between the first electrode and the second electrode,
wherein the light-emitting layer includes a base material, a first impurity element, a second impurity element, a third impurity element, and an organic compound,
wherein the base material is an inorganic compound including an element belonging to Group 2 of the periodic table and an element belonging to Group 16 of the periodic table, or an inorganic compound including an element belonging to Group 12 of the periodic table and an element belonging to Group 16 of the periodic table,
wherein the first impurity element is at least one of copper (Cu), silver (Ag), gold (Au), platinum (Pt), arsenic (As), phosphorus (P), and palladium (Pd),
wherein the second impurity element is at least one of fluorine (F), chlorine (Cl), bromine (Br), iodine (I), boron (B), aluminum (Al), gallium (Ga), indium (In), and thallium (Tl), and
wherein the third impurity element is at least one of manganese (Mn) and lanthanoid (Ln).

6. The light-emitting element according to claim 5, wherein the base material is selected from a group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, zinc-gallium oxide, strontium-gallium sulfide, barium-aluminum sulfide, barium-zinc sulfide, calcium-gallium sulfide, barium-silicon sulfide, and calcium aluminum sulfide.

7. A light-emitting device comprising the light-emitting element according to claim 5.

8. An electronic device comprising the light-emitting device according to claim 7 in a display portion.

9. A light-emitting element comprising:
a first electrode;
a second electrode; and
a light-emitting layer and an insulating layer between the first electrode and the second electrode,
wherein the insulating layer is in contact with the first electrode or the second electrode,
wherein the light-emitting layer includes a base material, a first impurity element, a second impurity element, and an organic compound,
wherein the base material is an inorganic compound including an element belonging to Group 2 of the periodic table and an element belonging to Group 16 of the periodic table, or an inorganic compound including an element belonging to Group 12 of the periodic table and an element belonging to Group 16 of the periodic table,
wherein the first impurity element is at least one of copper (Cu), silver (Ag), gold (Au), platinum (Pt), arsenic (As), phosphorus (P), and palladium (Pd), and
wherein the second impurity element is at least one of fluorine (F), chlorine (Cl), bromine (Br), iodine (I), boron (B), aluminum (Al), gallium (Ga), indium (In), and thallium (Tl).

10. The light-emitting element according to claim 9, wherein the base material is selected from a group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, zinc-gallium oxide, strontium-gallium sulfide, barium-aluminum sulfide, barium-zinc sulfide, calcium-gallium sulfide, barium-silicon sulfide, and calcium aluminum sulfide.

11. A light-emitting device comprising the light-emitting element according to claim 9.

12. An electronic device comprising the light-emitting device according to claim 11 in a display portion.

13. A light-emitting element comprising:
a first electrode;
a second electrode; and
a light-emitting layer, a first insulating layer, and a second insulating layer between the first electrode and the second electrode,
wherein the first insulating layer is in contact with the first electrode,
wherein the second insulating layer is in contact with the second electrode,
wherein the light-emitting layer includes a base material, a first impurity element, a second impurity element, and an organic compound,
wherein the base material is an inorganic compound including an element belonging to Group 2 of the periodic table and an element belonging to Group 16 of the periodic table, or an inorganic compound including an element belonging to Group 12 of the periodic table and an element belonging to Group 16 of the periodic table,
wherein the first impurity element is at least one of copper (Cu), silver (Ag), gold (Au), platinum (Pt), arsenic (As), phosphorus (P), and palladium (Pd), and
wherein the second impurity element is at least one of fluorine (F), chlorine (Cl), bromine (Br), iodine (I), boron (B), aluminum (Al), gallium (Ga), indium (In), and thallium (Tl).

14. The light-emitting element according to claim 13, wherein the base material is selected from a group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, zinc-gallium oxide, strontium-gallium sulfide, barium-aluminum sulfide, barium-zinc sulfide, calcium-gallium sulfide, barium-silicon sulfide, and calcium aluminum sulfide.

15. A light-emitting device comprising the light-emitting element according to claim 13.

16. An electronic device comprising the light-emitting device according to claim 15 in a display portion.

17. A light-emitting element comprising:
a first electrode;
a second electrode; and
a light-emitting layer and an insulating layer between the first electrode and the second electrode,
wherein the insulating layer is in contact with the first electrode or the second electrode,
wherein the light-emitting layer includes a base material, a first impurity element, a second impurity element, a third impurity element, and an organic compound,
wherein the base material is an inorganic compound including an element belonging to Group 2 of the periodic table and an element belonging to Group 16 of the periodic table, or an inorganic compound including an element belonging to Group 12 of the periodic table and an element belonging to Group 16 of the periodic table,
wherein the first impurity element is at least one of copper (Cu), silver (Ag), gold (Au), platinum (Pt), arsenic (As), phosphorus (P), and palladium (Pd),
wherein the second impurity element is at least one of fluorine (F), chlorine (Cl), bromine (Br), iodine (I), boron (B), aluminum (Al), gallium (Ga), indium (In), and thallium (Tl), and
wherein the third impurity element is at least one of manganese (Mn) and lanthanoid (Ln).

18. The light-emitting element according to claim 17, wherein the base material is selected from a group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, zinc-gallium oxide, strontium-gallium sulfide, barium-aluminum sulfide, barium-zinc sulfide, calcium-gallium sulfide, barium-silicon sulfide, and calcium aluminum sulfide.

19. A light-emitting device comprising the light-emitting element according to claim 17.

20. An electronic device comprising the light-emitting device according to claim 19 in a display portion.

21. A light-emitting element comprising:
a first electrode;
a second electrode; and
a light-emitting layer, a first insulating layer, and a second insulating layer between the first electrode and the second electrode,
wherein the first insulating layer is in contact with the first electrode,
wherein the second insulating layer is in contact with the second electrode,
wherein the light-emitting layer includes a base material, a first impurity element, a second impurity element, a third impurity element, and an organic compound,
wherein the base material is an inorganic compound including an element belonging to Group 2 of the periodic table and an element belonging to Group 16 of the periodic table, or an inorganic compound including an element belonging to Group 12 of the periodic table and an element belonging to Group 16 of the periodic table,
wherein the first impurity element is at least one of copper (Cu), silver (Ag), gold (Au), platinum (Pt), arsenic (As), phosphorus (P), and palladium (Pd),
wherein the second impurity element is at least one of fluorine (F), chlorine (Cl), bromine (Br), iodine (I), boron (B), aluminum (Al), gallium (Ga), indium (In), and thallium (Tl), and
wherein the third impurity element is at least one of manganese (Mn) and lanthanoid (Ln).

22. The light-emitting element according to claim 21, wherein the base material is selected from a group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, zinc-gallium oxide, strontium-gallium sulfide, barium-aluminum sulfide, barium-zinc sulfide, calcium-gallium sulfide, barium-silicon sulfide, and calcium aluminum sulfide.

23. A light-emitting device comprising the light-emitting element according to claim 21.

24. An electronic device comprising the light-emitting device according to claim 23 in a display portion.
